(19) United States
(12) Patent Application Publication
(10) Pub. No.: US 2023/0097671 A1
(43) Pub. Date: Mar. 30, 2023

(54) TOUCH SCREEN AND ELECTRONIC DEVICE

(71) Applicant: WUHAN CHINA STAR OPTOELECTRONICS SEMICONDUCTOR DISPLAY TECHNOLOGY CO., LTD., Wuhan (CN)

(72) Inventor: Lei WANG, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 17/052,814

(22) PCT Filed: Jun. 30, 2020
(86) PCT No.: PCT/CN2020/099375

§ 371 Date: Nov. 4, 2020

(30) Foreign Application Priority Data
Jun. 16, 2020 (CN) 202010546867.2

(51) Int. Cl. G06F 3/041

(52) U.S. Cl. CPC G06F 3/0412; H01L 27/322; H01L 27/323; H01L 27/3246; H01L 51/5253

(57) ABSTRACT

The present invention provides a touch screen and an electronic device. The touch screen includes: a driving substrate; a first conductive layer disposed on the driving substrate and including an anode and a first touch electrode, wherein the first touch electrode includes a plurality of first touch units; a barrier layer disposed on the first conductive layer; and a second conductive layer disposed on the barrier layer and including a second touch electrode, wherein the second touch electrode includes a plurality of second touch units.

### BACKGROUND OF INVENTION

### Field of Invention

The present invention relates to a field of display technology, in particular to a touch screen and an electronic device.

### Description of Prior Art

The existing touch screen includes a display panel and a touch layer. A polarizer is usually provided at a top of the display panel. The display panel usually uses an organic light-emitting diode display panel. Although the polarizer (POL) can effectively reduce the reflection of strong light, it will lose nearly 58% of the light output, thus increasing a burden of the organic light-emitting diode, that is, increasing power consumption. In addition, the polarizer (close to 100 um) cannot be used for flexible displays due to its relatively large thickness and brittle material.

Then came the technology of using color filters instead of polarizers (POL), that is, forming a color filter above the touch layer, which can not only reduce a thickness of the functional layer from 100 μm to less than 5 μm, but also improve a light exiting rate from 42% to 60%, so this technology is considered to be one of the key technologies for development of dynamic bending products.

However, the existing touch layer is provided on a encapsulation film of the display panel, so the thickness of the touch screen is increased.

### SUMMARY OF INVENTION

An object of the present invention is to provide a touch screen and an electronic device, which can reduce the thickness of the touch screen.

To solve the above technical problem, the present invention provides a touch screen, which includes:

a driving substrate;

a first conductive layer disposed on the driving substrate and including an anode and a first touch electrode, wherein the first touch electrode includes a plurality of first touch units;

a barrier layer disposed on the first conductive layer; and

a second conductive layer disposed on the barrier layer and including a second touch electrode, wherein the second touch electrode includes a plurality of second touch units, and the first touch units and the second touch units are arranged crosswise.

The present invention also provides an electronic device including the above touch screen. The electronic device includes, but is not limited to, a mobile phone, a tablet computer, a computer monitor, a gaming machine, a television, a wearable device, other household appliances or household appliances with display functions, or so on.

The touch screen and the electronic device of the present invention include a driving substrate; a first conductive layer disposed on the driving substrate and including an anode and a first touch electrode, wherein the first touch electrode includes a plurality of first touch units; a barrier layer disposed on the first conductive layer; and a second conductive layer disposed on the barrier layer and including a second touch electrode, wherein the second touch electrode includes a plurality of second touch units, and the first touch units and the second touch units are arranged crosswise. since the touch layer is embedded in the display panel, the thickness of the touch screen can be reduced.

### BRIEF DESCRIPTION OF DRAWINGS

FIG. 1 is a schematic structural diagram of an existing touch screen.

FIG. 2 is a schematic structural diagram of a touch screen according to an embodiment of the present invention.

FIG. 3 is a schematic structural diagram of a touch screen according to another embodiment of the present invention.

FIG. 4 is a schematic structural diagram of a touch screen according to still another embodiment of the present invention.

### DETAILED DESCRIPTION OF PREFERRED EMBODIMENTS

The following description of the various embodiments is provided to illustrate the specific embodiments of the invention. The spatially relative directional terms mentioned in the present invention, such as “upper”, “lower”, “before”, “after”, “left”, “right”, “inside”, “outside”, “side”, etc. and the like, may be used herein for ease of description to describe one element or feature's relationship to another element(s) or feature(s) as illustrated in the figures which are merely references. The spatially relative terms are intended to encompass different orientations in addition to the orientation as depicted in the figures.

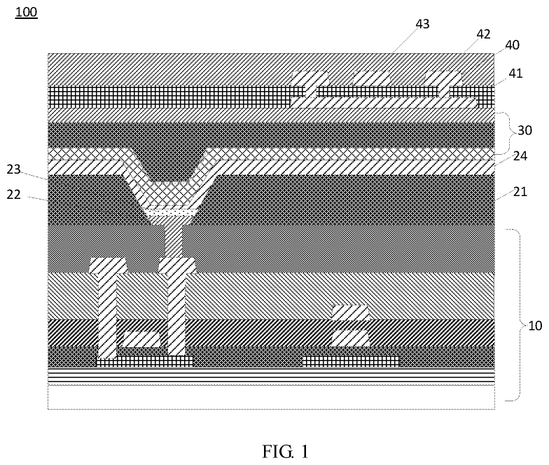

As shown in FIG. 1, the existing touch screen 100 includes a driving substrate 10, and a pixel definition layer 21, an anode layer 22, an organic light-emitting layer 23, a cathode 24, an encapsulation layer 30, and a touch layer 40 that are sequentially provided on the driving substrate 10. The touch layer 40 is disposed on the encapsulation layer 30. The touch layer 40 includes a first touch electrode 41 and a second touch electrode 42. The second touch electrode 42 is further provided with a planarization layer 43.

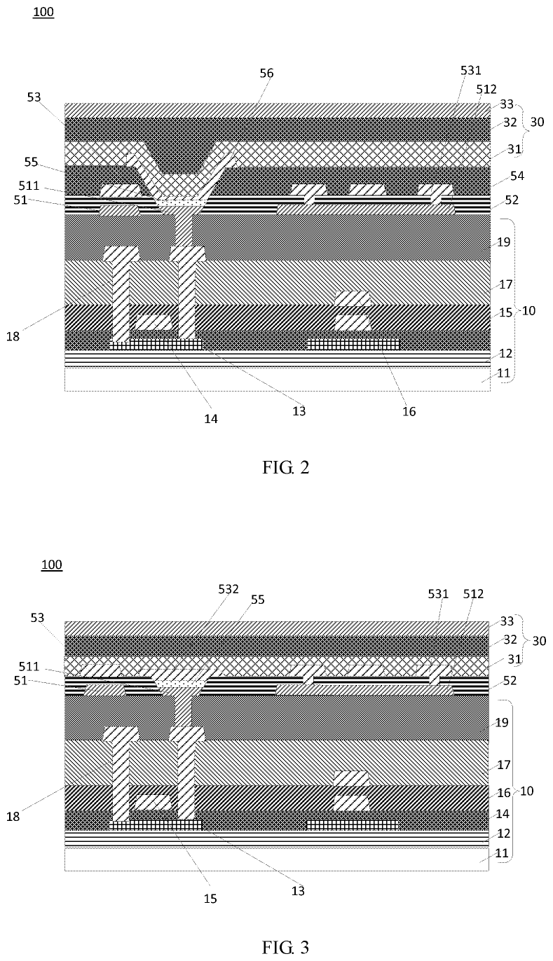

Referring to FIG. 2, FIG. 2 is a schematic structural diagram of a touch screen according to an embodiment of the present invention.

As shown in FIG. 2, the touch screen 100 of this embodiment includes a driving substrate 10, a first conductive layer 51, a barrier layer 52, a second conductive layer 53, an organic light-emitting layer 55, and a cathode 56.

The driving substrate 10 includes a flexible substrate 11 and a switch array layer, wherein material of the flexible substrate may include polyimide. The switch array layer is provided on the flexible substrate; the switch array layer may include a plurality of switch elements and has a cross-sectional structure including an active layer 13, a gate 14, and a source/drain 18. The switch element is, for example, a thin film transistor. In addition, the driving substrate further includes a buffer layer 12, a second insulating layer 15, a second electrode plate 16, a third insulating layer 17, and a fourth insulating layer 19. The buffer layer 12 is provided between the flexible substrate 11 and the active layer 13, the second insulating layer 15 is provided between the gate 14 and the second electrode plate 16, the third insulating layer 17 is provided between the second electrode plate 16 and the source/drain 18, and the fourth insulating layer 19 is provided on the source/drain 18.

The first conductive layer 51 is disposed on the third insulating layer 19; the first conductive layer 51 includes an anode 511 and a first touch electrode 512, and the first touch electrode 512 includes a plurality of first touch units (not shown).

The barrier layer 52 is disposed on the first conductive layer 51. The barrier layer 52 is made of an insulating material, which is not particularly limited.

The second conductive layer 53 is disposed on the barrier layer 52. The second conductive layer 53 includes a second touch electrode 531, and the second touch electrode 531 includes a plurality of second touch units (not shown). The first touch units and the second touch units are arranged crosswise. Specifically, an orthographic projection of the first touch units on the driving substrate crosses an orthographic projection of the second touch units on the driving substrate.

The cathode 56 is provided on the second conductive layer 53. An orthographic projection of the cathode 56 on the driving substrate 10 does not overlap both an orthographic projection of the first touch electrode 512 on the driving substrate and an orthographic projection of the second touch electrode 531 on the driving substrate.

The above-mentioned touch screen may further include a pixel definition layer 54 disposed between the second conductive layer 53 and the cathode 56, so that the planarization layer in the existing touch screen can be omitted, and the thickness of the touch screen is further reduced.

In an embodiment, each of the barrier layer 52 and the pixel definition layer 54 is provided with an opening area (not shown) thereon, and a position of the opening area corresponds to a position of the anode 511. The organic light-emitting layer 55 is located in the opening area; and the cathode 56 is provided on the organic light-emitting layer 55 and part of the pixel definition layer 54.

The touch screen may further include: an encapsulation film 30 provided on the cathode 56. In an embodiment, the encapsulation film 30 includes a first inorganic layer 31, an organic layer 32, and a second inorganic layer 33 provided on the cathode 56 sequentially.

In an embodiment, in order to improve the light exiting rate of the touch screen, the touch screen 100 may further include: a color filter layer (not shown), and the color filter layer is disposed on the encapsulation film 30. Of course, in other embodiments, the touch screen 100 may further include a polarizer (not shown), and the polarizer is disposed on the encapsulation film 30.

Referring to FIG. 3, FIG. 3 is a schematic structural diagram of a touch screen according to another embodiment of the present invention.

The touch screen of this embodiment is different from that of the previous embodiment in that the cathode and the second touch electrode are on the same layer. Specifically, the second conductive layer 53 may further include a cathode 532, where the second touch electrode 531 and the cathode 532 are spaced apart from each other. Since the cathode and the second touch electrode are made on the same layer, an insulating layer (that is the pixel definition layer), to further reduce the thickness of the touch screen.

The opening area is provided on the barrier layer 52; the organic light-emitting layer 55 is located in the opening area; and the second conductive layer 53 is provided on the organic light-emitting layer 55 and the barrier layer 52.

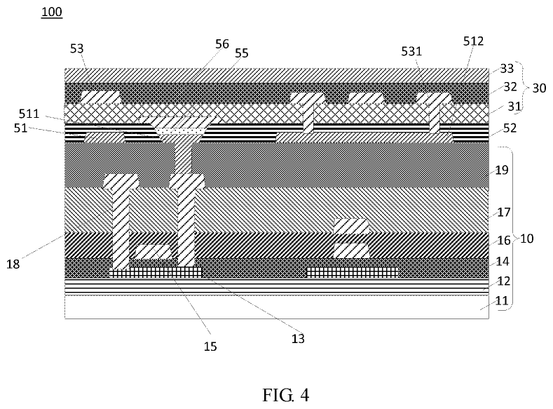

Referring to FIG. 4, FIG. 4 is a schematic structural diagram of a touch screen according to still another embodiment of the present invention.

The touch screen of this embodiment is different from that of the first embodiment in that the second conductive layer is embedded in the encapsulation film.

In this embodiment, the cathode 56 is provided on the barrier layer 52, the encapsulation film 30 is provided on the cathode 56, and the second conductive layer 53 is located in the encapsulation film 30.

In an embodiment, the second conductive layer 53 is located between the first inorganic layer 31 and the organic layer 32. Of course, the second conductive layer 53 may also be disposed between the organic layer 32 and the second inorganic layer 33. Arrangement of the second conductive layer is not particularly limited to this.

Since the second conductive layer is embedded in the encapsulation film, one insulating layer (pixel definition layer) can be omitted, such that the thickness of the touch screen can be further reduced, and the sensitivity of the touch function can be improved.

The present invention also provides an electronic device including the above touch screen. The electronic device includes, but is not limited to, a mobile phone, a tablet computer, a computer monitor, a gaming machine, a television, a wearable device, other household appliances or household appliances with display functions, or so on.

The touch screen and the electronic device of the present invention include a driving substrate; a first conductive layer disposed on the driving substrate and including an anode and a first touch electrode, wherein the first touch electrode includes a plurality of first touch units; a barrier layer disposed on the first conductive layer; and a second conductive layer disposed on the barrier layer and including a second touch electrode, wherein the second touch electrode includes a plurality of second touch units, and the first touch units and the second touch units are arranged crosswise. since the touch layer is embedded in the display panel, the thickness of the touch screen can be reduced.

While the invention has been described by way of example and in terms of the preferred embodiments, it is to be understood that the invention is not limited to the disclosed embodiments. To the contrary, it is intended to cover various modifications and similar arrangements. Therefore, the scope of the appended claims should be accorded the broadest interpretation so as to encompass all such modifications and similar arrangements.

What is claimed is:

1. A touch screen, comprising:
a driving substrate;
a first conductive layer disposed on the driving substrate and comprising an anode and a first touch electrode, wherein the first touch electrode comprises a plurality of first touch units;
a barrier layer disposed on the first conductive layer; and
a second conductive layer disposed on the barrier layer and comprising a second touch electrode, wherein the second touch electrode comprises a plurality of second touch units, and the first touch units and the second touch units are arranged crosswise.

2. The touch screen according to claim 1, further comprising:
a cathode disposed on the second conductive layer, wherein an orthographic projection of the cathode on the driving substrate does not overlap both an orthographic projection of the first touch electrode on the driving substrate and an orthographic projection of the second touch electrode on the driving substrate.

3. The touch screen according to claim 2, further comprising:
a pixel definition layer disposed between the second conductive layer and the cathode.

4. The touch screen according to claim 3, wherein
each of the barrier layer and the pixel definition layer is provided with an opening area thereon, and a position of the opening area corresponds to a position of the anode;
the touch screen further comprises: an organic light-emitting layer located in the opening area; and
the cathode is disposed on the organic light-emitting layer and part of the pixel definition layer.

5. The touch screen according to claim 2, further comprising:
an encapsulation film disposed on the cathode.

6. The touch screen according to claim 5, further comprising:
a color filter layer disposed on the encapsulation film.

7. The touch screen according to claim 2, further comprising: an encapsulation film, wherein
the cathode is disposed on the barrier layer; and
the encapsulation film is disposed on the cathode, and the second conductive layer is located in the encapsulation film.

8. The touch screen according to claim 7, wherein the encapsulation film comprises: a first inorganic layer, an organic layer, and a second inorganic layer disposed on the cathode sequentially; and
the second conductive layer is located between the first inorganic layer and the organic layer.

9. The touch screen according to claim 1, wherein
the second conductive layer comprises a cathode spaced apart from the second touch electrode.

10. The touch screen according to claim 9, further comprising: an organic light-emitting layer, wherein
the opening area is disposed on the barrier layer;
the organic light-emitting layer is located in the opening area; and
the second conductive layer is disposed on the organic light-emitting layer and the barrier layer.

11. An electronic device, comprising a touch screen, wherein the touch screen comprises:
a driving substrate;
a first conductive layer disposed on the driving substrate and comprising an anode and a first touch electrode, wherein the first touch electrode comprises a plurality of first touch units;
a barrier layer disposed on the first conductive layer; and
a second conductive layer disposed on the barrier layer and comprising a second touch electrode, wherein the second touch electrode comprises a plurality of second touch units, and the first touch units and the second touch units are arranged crosswise.

12. The electronic device according to claim 11, wherein the touch screen further comprises:
a cathode disposed on the second conductive layer, wherein an orthographic projection of the cathode on the driving substrate does not overlap both an orthographic projection of the first touch electrode on the driving substrate and an orthographic projection of the second touch electrode on the driving substrate.

13. The electronic device according to claim 12, wherein the touch screen further comprises:
a pixel definition layer disposed between the second conductive layer and the cathode.

14. The electronic device according to claim 13, wherein
each of the barrier layer and the pixel definition layer is provided with an opening area thereon, and a position of the opening area corresponds to a position of the anode;
the touch screen further comprises: an organic light-emitting layer located in the opening area; and
the cathode is disposed on the organic light-emitting layer and part of the pixel definition layer.

15. The electronic device according to claim 12, wherein the touch screen further comprises:
an encapsulation film is disposed on the cathode.

16. The electronic device according to claim 15, wherein the touch screen further comprises:
a color filter layer disposed on the encapsulation film.

17. The electronic device according to claim 12, wherein the touch screen further comprises: an encapsulation film, wherein
the cathode is disposed on the barrier layer; and
the encapsulation film is disposed on the cathode, and the second conductive layer is located in the encapsulation film.

18. The electronic device according to claim 17, wherein the encapsulation film comprises: a first inorganic layer, an organic layer, and a second inorganic layer disposed on the cathode sequentially; and
the second conductive layer is located between the first inorganic layer and the organic layer.

19. The electronic device according to claim 11, wherein
the second conductive layer comprises a cathode spaced apart from the second touch electrode.

20. The electronic device according to claim 19, wherein the touch screen further comprises: an organic light-emitting layer;
the opening area is disposed on the barrier layer;
the organic light-emitting layer is located in the opening area; and
the second conductive layer is disposed on the organic light-emitting layer and the barrier layer.
